(19) United States
(12) Patent Application Publication
(10) Pub. No.: US 2025/0324602 A1
(43) Pub. Date: Oct. 16, 2025

(54) SEMICONDUCTOR STRUCTURES IN THREE-DIMENSIONAL MEMORY DEVICES

(71) Applicant: Yangtze Memory Technologies Co., Ltd., Wuhan (CN)

(72) Inventors: Li XIANG, Wuhan (CN); Yulu YANG, Wuhan (CN); Ke LIANG, Wuhan (CN)

(21) Appl. No.: 18/776,200

(22) Filed: Jul. 17, 2024

Related U.S. Application Data
(63) Continuation of application No. PCT/CN2024/087928, filed on Apr. 16, 2024.

(51) Int. Cl. H10B 43/40; G11C 16/08; H01L 23/00; H01L 25/065; H01L 25/18; H10B 41/10; H10B 41/41; H10B 43/10; H10B 80/00

(52) U.S. Cl. CPC H10B 43/40; G11C 16/08; H01L 24/08; H01L 25/0657; H01L 25/18; H10B 41/10; H10B 41/41; H10B 43/10; H10B 80/00; H01L 2224/08145; H01L 2924/1431; H01L 2924/14511

(57) ABSTRACT

Methods, devices, and systems for managing layouts of semiconductor structures in three-dimensional (3D) memory devices are provided. In one aspect, a memory device includes a first semiconductor structure and a second semiconductor structure. The first semiconductor structure includes a first memory array in a first array region, a second memory array in a second array region, and word lines coupled to memory cells in the first memory array and memory cells in the second memory array. The second semiconductor structure includes row decoders. The first semiconductor structure and the second semiconductor structure are stacked together along a second direction perpendicular to the first direction. At least one part of the row decoders overlaps with at least one of the first memory array in the first array region or the second memory array in the second array region in a plan view perpendicular to the second direction.

### CROSS-REFERENCE TO RELATED APPLICATIONS

This application is a continuation of International Application No. PCT/CN2024/087928, filed on Apr. 16, 2024, the disclosure of which is hereby incorporated by reference in its entirety.

### TECHNICAL FIELD

The present disclosure relates to semiconductor devices, e.g., 3D memory devices.

### BACKGROUND

Semiconductor devices, e.g., memory devices, can have various structures to increase a density of memory cells and lines on a chip. For example, three-dimensional (3D) memory devices are attractive due to their capability to increase an array density by stacking more layers within a similar footprint. A 3D memory device normally includes a memory array of memory cells and peripheral circuits for facilitating operations of the memory array.

### SUMMARY

The present disclosure describes managing layouts of semiconductor structures in three-dimensional (3D) memory devices.

One aspect of the present disclosure features a memory device, including a first semiconductor structure and a second semiconductor structure. The first semiconductor structure includes a first memory array in a first array region, a second memory array in a second array region, contact structures in a connection region between the first array region and the second array region along a first direction, and word lines coupled to memory cells in the first memory array and memory cells in the second memory array. The second semiconductor structure includes row decoders. The first semiconductor structure and the second semiconductor structure are stacked together along a second direction perpendicular to the first direction. At least one part of the row decoders overlaps with at least one of the first memory array in the first array region or the second memory array in the second array region in a plan view perpendicular to the second direction.

In some implementations, the second semiconductor structure further includes string drivers. A string driver of the string drivers is coupled to a corresponding word line through a contact structure in the connection region. The string driver is also coupled to a corresponding row decoder. At least a first part of the string drivers overlaps with the at least one of the first memory array in the first array region or the second memory array in the second array region in the plan view.

In some implementations, a second part of the string drivers overlaps with the contact structures in the connection region in the plan view.

In some implementations, the row decoders are positioned adjacent to the string drivers along the first direction.

In some implementations, the row decoders are positioned on one side of the string drivers.

In some implementations, the row decoders include a first group of row decoders and a second group of row decoders. The first group of row decoders is positioned on a first side of the string drivers, and the second group of row decoders is positioned on a second side of the string drivers.

In some implementations, the first semiconductor structure includes N memory blocks numbered from 0 to N-1. The first group of row decoders includes a first row decoder coupled to first string drivers that are coupled to word lines in a first memory block associated with an odd number. The second group of row decoders includes a second row decoder coupled to second string drivers that are coupled to word lines in a second memory block associated with an even number.

In some implementations, the first string drivers and the second string drivers are between the first row decoder and the second row decoder along the first direction, where the odd number and the even number are adjacent integers.

In some implementations, the second semiconductor structure further includes a first group of page buffers and a second group of page buffers. The row decoders and the string drivers are positioned between the first group of page buffers and the second group of page buffers along the first direction.

In some implementations, the first semiconductor structure further includes bit lines coupled to the memory cells in the first memory array. The bit lines are coupled to corresponding page buffers of the first group of page buffers. At least a first part of one of the bit lines is distanced from a corresponding page buffer along the first direction in the plan view.

In some implementations, the one of the bit lines is coupled to the corresponding page buffer through a first connection line in the first semiconductor structure and a second connection line in the second semiconductor structure. The second connection line comprises a first part overlapping with at least one of the row decoders or the string drivers, a second part overlapping with the first group of page buffers, and a third part connecting ends of the first part and the second part.

In some implementations, the first semiconductor structure includes a first bonding layer including first conductive structures isolated by a first isolating material. The second semiconductor structure includes a second bonding layer including second conductive structures isolated by a second isolating material. The first semiconductor structure and the second semiconductor structure are bonded together with the first conductive structures being in contact with the second conductive structures.

In some implementations, the memory device includes a NAND memory device.

Another aspect of the present disclosure features a method of forming a memory device, including forming a first semiconductor structure, forming a second semiconductor structure. The first semiconductor structure includes a first memory array in a first array region, a second memory array in a second array region, contact structures in a connection region between the first array region and the second array region along a first direction, and word lines coupled to memory cells in the first memory array and memory cells in the second memory array. The second semiconductor structure includes row decoders. The method further includes stacking the first semiconductor structure and the second semiconductor structure along a second direction perpendicular to the first direction. At least one part of the row decoders overlaps with at least one of the first memory array in the first array region or the second memory array in the second array region in a plan view perpendicular to the second direction.

In some implementations, the second semiconductor structure further includes string drivers. A string driver of the string drivers is coupled to a corresponding word line through a contact structure in the connection region. The string driver is also coupled to a corresponding row decoder. At least a first part of the string drivers overlaps with the at least one of the first memory array in the first array region or the second memory array in the second array region in the plan view.

In some implementations, a second part of the string drivers overlaps with the contact structures in the connection region in the plan view.

In some implementations, the row decoders include a first group of row decoders and a second group of row decoders. The first group of row decoders is positioned on a first side of the string drivers, and the second group of row decoders is positioned on a second side of the string drivers.

In some implementations, the first semiconductor structure includes N memory blocks numbered from 0 to N-1. The first group of row decoders includes a first row decoder coupled to first string drivers that are coupled to word lines in a first memory block associated with an odd number. The second group of row decoders includes a second row decoder coupled to second string drivers that are coupled to word lines in a second memory block associated with an even number.

In some implementations, the first string drivers and the second string drivers are between the first row decoder and the second row decoder along the first direction, where the odd number and the even number are adjacent integers.

In some implementations, the second semiconductor structure further includes a first group of page buffers and a second group of page buffers. The row decoders and the string drivers are positioned between the first group of page buffers and the second group of page buffers along the first direction. The first semiconductor structure further includes bit lines coupled to the memory cells in the first memory array. The bit lines are coupled to corresponding page buffers of the first group of page buffers. At least one part of one of the bit lines is distanced from a corresponding page buffer along the first direction in the plan view.

Another aspect of the present disclosure features a system including a memory device and a controller coupled to the memory device and configured to control the memory device. The memory device includes a first semiconductor structure and a second semiconductor structure. The first semiconductor structure includes a first memory array in a first array region, a second memory array in a second array region, contact structures in a connection region between the first array region and the second array region along a first direction, and word lines coupled to memory cells in the first memory array and memory cells in the second memory array. The second semiconductor structure includes row decoders. The first semiconductor structure and the second semiconductor structure are stacked together along a second direction perpendicular to the first direction. At least one part of the row decoders overlaps with at least one of the first memory array in the first array region or the second memory array in the second array region in a plan view perpendicular to the second direction.

The details of one or more implementations of the subject matter of this present disclosure are set forth in the accompanying drawings and the description below. Other features, aspects, and advantages of the subject matter will become apparent from the description, the drawings, and the claims.

### BRIEF DESCRIPTION OF THE DRAWINGS

The accompanying drawings, which are incorporated herein and form a part of the present disclosure, illustrate aspects of the present disclosure and, together with the description, further serve to explain the principles of the present disclosure and to enable a person of ordinary skill in the pertinent art to make and use the present disclosure.

FIG. 1A illustrates a schematic view of a cross-section of an example 3D memory device.

FIG. 1B illustrates a schematic view of a cross-section of an example 3D memory device.

FIG. 2 illustrates an example of a schematic circuit diagram of an example memory device including peripheral circuits.

FIG. 3 illustrates example peripheral circuits.

FIG. 4 illustrates schematic circuit diagrams of example word line drivers and page buffers of FIG. 3.

FIG. 5 illustrates a top view of an example first semiconductor structure.

FIG. 6A illustrates a plan view of an example second semiconductor structure.

FIG. 6B illustrates a plan view of an example 3D memory device having the second semiconductor structure of FIG. 6A.

FIG. 7A illustrates a plan view of another example second semiconductor structure.

FIG. 7B illustrates a plan view of an example 3D memory device having the second semiconductor structure of FIG. 7A.

FIG. 8A illustrates a plan view of another example second semiconductor structure.

FIG. 8B illustrates a plan view of an example 3D memory device having the second semiconductor structure of FIG. 8A.

FIG. 9 is a flow chart of an example process of forming a memory device.

FIG. 10 illustrates a block diagram of an example system having one or more memory devices.

FIG. 11A illustrates a diagram of a memory card having an example memory device.

FIG. 11B illustrates a diagram of a solid-state drive (SSD) having an example memory device.

Like reference numbers and designations in the various drawings indicate like elements. It is also to be understood that the various exemplary implementations shown in the figures are merely illustrative representations and are not necessarily drawn to scale.

### DETAILED DESCRIPTION

As memory cell density of a three-dimensional (3D) memory device increases, the 3D memory device has an increased quantity of string drivers, which can occupy a larger area on a chip. The 3D memory device can be a bonded chip including a first semiconductor structure and a second semiconductor structure that are separately formed on different substrates and then stacked together to form the bonded chip. The first semiconductor structure can include a first memory array in a first array region, a second memory array in a second array region, and a connection region positioned between the first array region and the second array region. The second semiconductor structure can include peripheral circuits including a first group of page buffers, a second group of page buffers, string drivers and row decoders.

Implementations of the present disclosure provide techniques for managing layouts of semiconductor structures (e.g., the first semiconductor structure and the second semiconductor structure) in a 3D memory device. For example, to balance chip size and program speed, the string drivers and the row decoders can be positioned between the first group of page buffers and the second group of page buffers in the second semiconductor structure of the 3D memory device.

In some cases, the string drivers and the row decoders are positioned out of the first and second memory arrays. That is, in a plan view along a stacking direction, the string drivers and the row decoders of the second semiconductor structure do not overlap with the first memory array or the second memory array of the first semiconductor structure. At least one of the string drivers or the row decoders overlap with the connection region of the first semiconductor structure. Since the string drivers and the row decoders occupy a larger area than the connection region, some regions in the first semiconductor structure may be wasted with a potential to accommodate more memory cells.

With advancements in CMOS technology, the width (e.g., length along word line direction) of the first group of page buffers and the second group of page buffers can be reduced. In some implementations, the string drivers or the row decoders are positioned under the first or second memory arrays. That is, in the plan view along the stacking direction, the string drivers or the row decoders of the second semiconductor structure at least partially overlap with the first memory array or the second memory array of the first semiconductor structure.

In some implementations, the row decoders are symmetrically positioned on both sides of the string drivers. For example, row decoders associated with even-numbered memory blocks are positioned on a first side of the string drivers, and row decoders associated with odd-numbered memory blocks are positioned on a second side of the string drivers.

Implementations of the present disclosure can provide one or more of the following technical advantages. For example, except for the connection region, regions in the first semiconductor structure can all be utilized to accommodate memory cells, which can increase the memory cell density of the 3D memory device. Moreover, by symmetrically positioning the row decoders on both sides of the string drivers, fewer metal layers are used to connect the row decoders with the string drivers, which leaves more metal layers to connect bit lines in the first semiconductor structure with corresponding page buffers in the second semiconductor structure. In addition, by adopting the layout structure where the string drivers or the row decoders are positioned under the memory arrays, the size of the first and second semiconductor structures can be reduced, which can reduce the chip size of the 3D memory device.

The techniques can be applied to various types of semiconductor devices, or non-volatile memory (NVM) devices, such as NAND flash memory, NOR flash memory, resistive random-access memory (RRAM), phase-change memory (PCM) such as phase-change random-access memory (PCRAM), spin-transfer torque (STT)-Magnetoresistive random-access memory (MRAM), or volatile memory devices, such as DRAM memory devices, among others. The techniques can also be applied to charge-trapping based memory devices, e.g., silicon-oxide-nitride-oxide-silicon (SONOS) memory devices, and floating-gate based memory devices. The techniques can be applied to three-dimensional (3D) memory devices. The techniques can be applied to various memory types, such as SLC (single-level cell) devices, MLC (multi-level cell) devices like 2-level cell devices, TLC (triple-level cell) devices, QLC (quad-level cell) devices, or PLC (penta-level cell) devices. Additionally, or alternatively, the techniques can be applied to various types of devices and systems, such as secure digital (SD) cards, embedded multimedia cards (eMMC), or solid-state drives (SSDs), embedded systems, among others.

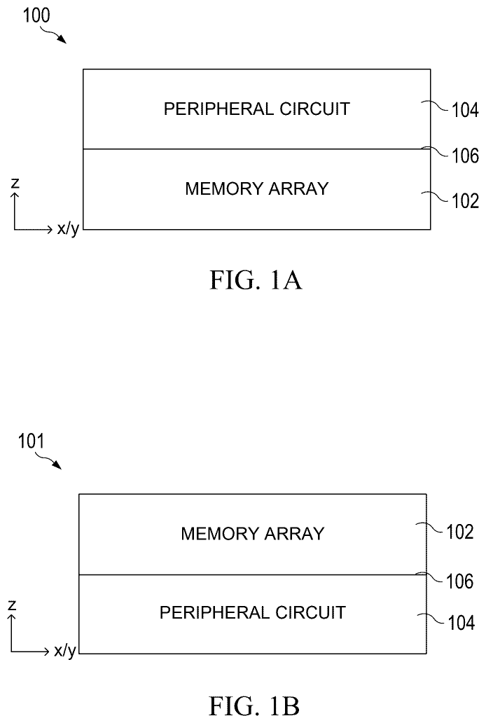

FIG. 1A illustrates a schematic view of a cross-section of an example 3D memory device 100, according to one or more implementations of the present disclosure. 3D memory device 100 represents an example of a bonded chip. The components of 3D memory device 100 (e.g., memory array and peripheral circuits) can be formed separately on different substrates and then jointed to form a bonded chip. 3D memory device 100 can include a first semiconductor structure 102 including an array of memory cells (i.e., memory array). In some implementations, the memory array includes an array of NAND Flash memory cells. For ease of description, a NAND Flash memory array may be used as an example for describing the memory array in the present disclosure. But it is understood that the memory array is not limited to NAND Flash memory array and may include any other suitable types of memory arrays, such as dynamic random access memory (DRAM) cell array, static random access memory (SRAM) cell array, NOR Flash memory array, phase change memory (PCM) cell array, resistive memory array, magnetic memory array, spin transfer torque (STT) memory array, to name a few, or any combination thereof.

The first semiconductor structure 102 can be a NAND Flash memory device in which memory cells are provided in the form of an array of 3D NAND memory strings and/or an array of two-dimensional (2D) NAND memory cells. NAND memory cells can be organized into pages or fingers, which are then organized into blocks in which each NAND memory cell is electrically connected to a separate line called a bit line (BL). All cells with the same vertical position in the NAND memory block can be electrically connected through the control gates by a word line (WL). In some implementations, a plane contains a certain number of blocks that are electrically connected through the same bit line. The first semiconductor structure 102 can include one or more planes, and the peripheral circuits that are needed to perform all the read/program (write)/erase operations can be included in a second semiconductor structure 104.

In some implementations, the array of NAND memory cells is an array of 2D NAND memory cells, each of which includes a floating-gate transistor. The array of 2D NAND memory cells include a plurality of 2D NAND memory strings, each of which includes a plurality of memory cells (e.g., 32 to 128 memory cells) connected in series (resembling a NAND gate) and two select transistors, according to some implementations. Each 2D NAND memory string is arranged in the same plane on the substrate (in 2D), according to some implementations. In some implementations, the array of NAND memory cells is an array of 3D NAND memory strings, each of which extends vertically above the substrate (in 3D) through a stack structure, e.g., a memory stack. Depending on the 3D NAND technology (e.g., the number of layers/tiers in the memory stack), a 3D NAND memory string typically includes 32 to 256 NAND memory cells, each of which includes a floating-gate transistor or a charge-trap transistor.

As shown in FIG. 1A, 3D memory device 100 can also include the second semiconductor structure 104 including the peripheral circuits of the memory array of the first semiconductor structure 102. The peripheral circuits (a.k.a. control and sensing circuits) can include any suitable digital, analog, and/or mixed-signal circuits used for facilitating the operations of the memory array. For example, the peripheral circuit can include one or more of a page buffer, a decoder (e.g., a row decoder and a column decoder), a sense amplifier, a driver (e.g., a word line driver), an I/O circuit, a charge pump, a voltage source or generator, a current or voltage reference, any portions (e.g., a sub-circuit) of the functional circuits mentioned above, or any active or passive components of the circuit (e.g., transistors, diodes, resistors, or capacitors). The peripheral circuits in second semiconductor structure 104 use CMOS technology, e.g., which can be implemented with logic processes (e.g., technology nodes of 90 nm, 65 nm, 60 nm, 45 nm, 32 nm, 28 nm, etc.). As described above and below in detail, consistent with the scope of the present disclosure, the technology nodes used for fabricating the peripheral circuits in second semiconductor structure 104 are above 22 nm in order to reduce leakage current, maintain certain voltage levels (e.g., 1.2 V and above), and reduce the cost.

As shown in FIG. 1A, 3D memory device 100 further includes a bonding interface 106 vertically (e.g., along Z direction) between first semiconductor structure 102 and second semiconductor structure 104. In some implementations, the first and the second semiconductor structures 102 and 104 can be fabricated separately (and in parallel in some implementations) such that the thermal budget of fabricating one of first and second semiconductor structures 102 and 104 does not limit the processes of fabricating another one of first and second semiconductor structures 102 and 104. Moreover, a large number of interconnects can be formed through bonding interface 106 to make direct, short-distance (e.g., micron-level) electrical connections between first semiconductor structure 102 and second semiconductor structure 104, as opposed to the long-distance (e.g., millimeter or centimeter-level) chip-to-chip data bus on the circuit board, such as printed circuit board (PCB), thereby eliminating chip interface delay and achieving high-speed I/O throughput with reduced power consumption. Data transfer between the memory array in first semiconductor structure 102 and the peripheral circuits in second semiconductor structure 104 can be performed through the interconnects across the bonding interface 106. By vertically (e.g., along Z direction) integrating first and second semiconductor structures 102 and 104, the chip size can be reduced, and the memory cell density can be increased.

It is understood that the relative positions of stacked first and second semiconductor structures 102 and 104 are not limited. FIG. 1B illustrates a schematic view of a cross-section of an example 3D memory device 101, according to one or more implementations of the present disclosure. Different from 3D memory device 100 of FIG. 1A in which second semiconductor structure 104 including the peripheral circuits is above first semiconductor structure 102 including the memory array, in 3D memory device 101 of FIG. 1B, first semiconductor structure 102 including the memory array is above second semiconductor structure 104 including the peripheral circuits. Nevertheless, bonding interface 106 is formed vertically between first and second semiconductor structures 102 and 104 in 3D memory device 101, and first and second semiconductor structures 102 and 104 are jointed vertically through bonding (e.g., hybrid bonding) according to some implementations. Hybrid bonding, also known as “metal/dielectric hybrid bonding,” is a direct bonding technology (e.g., forming bonding between surfaces without using intermediate layers, such as solder or adhesives) and can obtain metal-metal (e.g., Cu-to-Cu) bonding and dielectric-dielectric (e.g., SiO₂-to-SiO₂) bonding simultaneously. Data transfer between the memory array in first semiconductor structure 102 and the peripheral circuits in second semiconductor structure 104 can be performed through the interconnects across bonding interface 106. In some implementations, the bonding interface 106 can include a first bonding layer in the first semiconductor structure 102 and a second bonding layer in the second semiconductor structure 104. The first bonding layer can include first conductive structures isolated by a first isolating material (e.g., SiO₂ or other dielectric material). The second bonding layer can include second conductive structures isolated by a second isolating material (e.g., SiO₂ or other dielectric material). The first isolating material and the second isolating material can be same or different, e.g., according to actual fabrication needs. Each of the second conductive structures can correspond to a first conductive structure of the first conductive structures. As such, when the first semiconductor structure 102 and the second semiconductor structure 104 are stacked together, the second conductive structures can be in contact with the corresponding first conductive structures to form conductive bonding (e.g., metal-to-metal bonding) through the bonding interface 106.

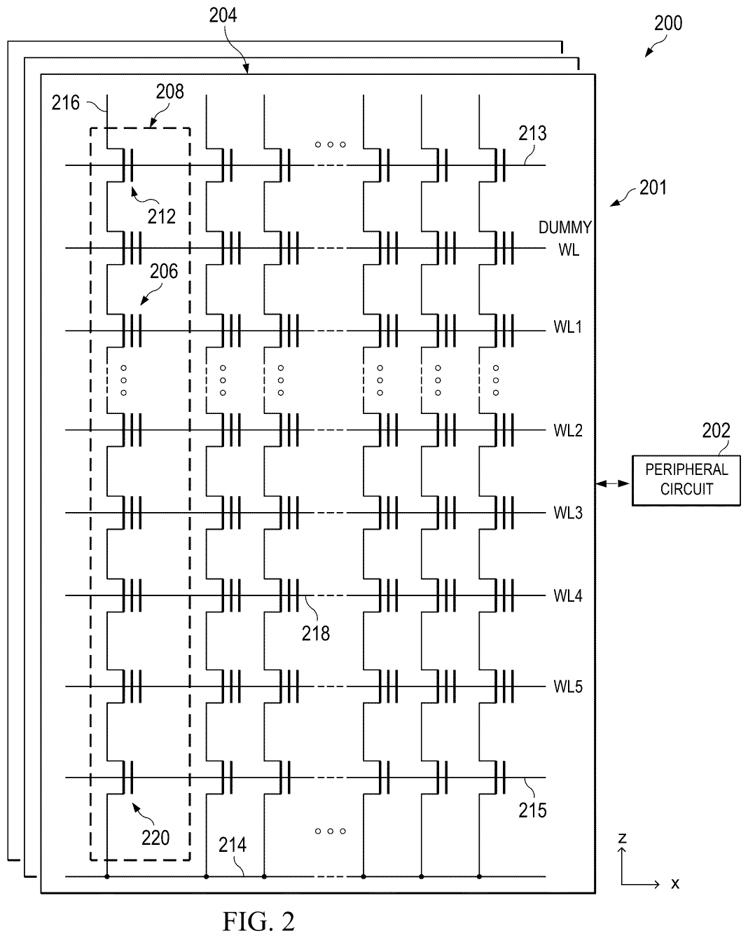

FIG. 2 illustrates an example of a schematic circuit diagram of an example memory device 200 (e.g., the 3D memory device 100 of FIG. 1A, the 3D memory device 101 of FIG. 1B) including peripheral circuits, according to one or more implementations of the present disclosure. The memory device 200 can include a memory array 201 and peripheral circuits 202 coupled to the memory array 201. The memory array 201 can be a NAND Flash memory array in which memory cells 206 are provided in the form of an array of NAND memory strings 208 each extending vertically above a substrate, e.g., a semiconductor substrate such as a wafer. In some implementations, each NAND memory string 208 includes a plurality of memory cells 206 coupled in series and stacked vertically (e.g., along Z direction). Each memory cell 206 can hold a continuous, analog value, such as an electrical voltage or charge that depends on the number of electrons trapped within a storage layer of the memory cell 206. The logic state (i.e., data) of each memory cell 206 in the block 204 can be determined based on the threshold voltage of the memory cell 206. Each memory cell 206 can be a floating gate type memory cell including a floating-gate transistor, or a charge trap type memory cell including a charge-trap transistor.

In some implementations, each memory cell 206 is a single-level cell (SLC) with two possible memory states that can store one bit of data. For example, the first memory state “0” can correspond to a first range of voltages, and the second memory state “1” can correspond to a second range of voltages. In some implementations, each memory cell 206 is a multi-level cell (MLC) that is capable of storing more than one bit of data in more than two memory states. For example, the MLC can store two bits per cell, three bits per cell (also known as triple-level cell (TLC)), or four bits per cell (also known as a quad-level cell (QLC)). Each MLC can be programmed to support a range of possible nominal storage values. In one example, if each MLC stores two bits of data, then the MLC can be programmed to one of three possible programming levels from an erased state by writing one of three possible nominal storage values to the cell. A fourth nominal storage value can be used for the erased state.

As shown in FIG. 2, each NAND memory string 208 can include a source select gate (SSG) 210 at its source end and a drain select gate (DSG) 212 at its drain end. The SSG 210 and the DSG 212 can be configured to activate selected NAND memory strings 208 (columns of the array) during read and program operations. In some implementations, the sources of NAND memory strings 208 in the same block 204 are coupled through a same source line (SL) 214, e.g., a common SL. In other words, NAND memory strings 208 in the same block 204 have an array common source (ACS), according to some implementations. The DSG 212 of each NAND memory string 208 is coupled to a respective bit line 216 from which data can be read or written via an output bus (not shown), according to some implementations. In some implementations, the bit line 216 can extend along a horizontal direction (e.g., Y direction) to couple more than one memory string 208. In some implementations, each NAND memory string 208 is configured to be selected or deselected by applying a select voltage (e.g., above the threshold voltage of the transistor having the DSG 212) or a deselect voltage (e.g., 0 V) to the respective DSG 212 through one or more DSG lines 213, and/or by applying a select voltage (e.g., above the threshold voltage of the transistor having the SSG 210) or a deselect voltage (e.g., 0 V) to the respective SSG 210 through one or more SSG lines 215.

As shown in FIG. 2, NAND memory strings 208 can be organized into multiple blocks 204, each of which can have a common source line 214 coupled to the ACS. In some implementations, each block 204 can serve as a basic data unit for erase operations, such that memory cells 206 on the same block 204 are erased at the same time. To erase memory cells 206 in a selected block 204, the source lines 214 coupled to the selected block 204 and unselected blocks in the same plane can be biased with an erase voltage. For example, the erase voltage can be a high positive voltage (e.g., 20 V or more). In some implementations, an erase operation can be performed at a half-block level, a quarter-block level, or a level having any suitable number of blocks or fractions of a block.

The memory cells 206 of adjacent NAND memory strings 208 can be coupled through word lines 218. In some implementations, the word line 218 can extend along a horizontal direction (e.g., X direction). The word line 218 can select which row of memory cells 206 is affected by read and program operations. In some implementations, the memory cell 206 is a SLC, and each word line 218 is coupled to a page of memory cells 206, which is the basic data unit for program operations. If the memory cell 206 is an MLC that stores two bits of data per cell, each word line 218 can correspond to two pages. If memory cell 206 is a TLC, each word line 218 can correspond to three pages. If memory cell 206 is a QLC, each word line 218 can correspond to four pages. The size of a page in bits is associated with the number of NAND memory strings 208 coupled by word line 218 in a block 204. Each word line 218 can include a gate line coupled to a plurality of control gates (gate electrodes) of a plurality of memory cells 206 in the respective page. Example word lines shown in FIG. 2 include dummy WL, WL1, WL2, WL3, WL4, and WL5 that are between one or more DSG lines 213 and one or more SSG lines 215.

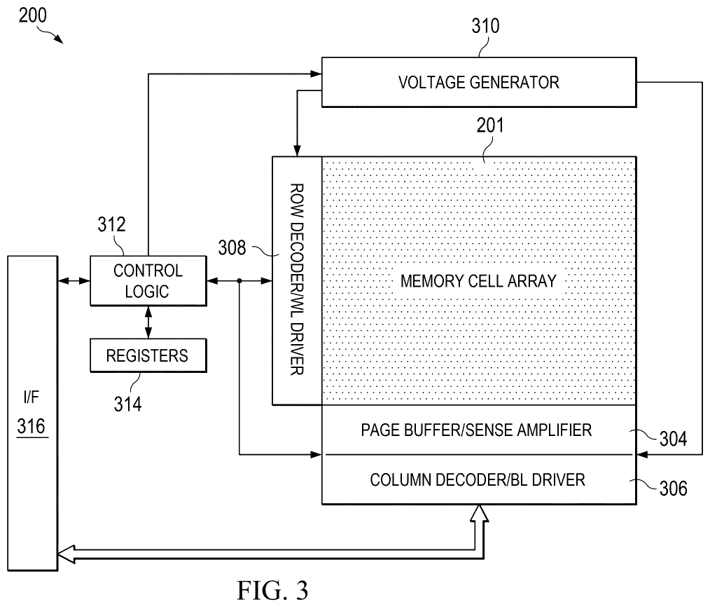

FIG. 3 illustrates example peripheral circuits 202, according to one or more implementations of the present disclosure. The peripheral circuits 202 can be coupled to the memory array 201 through bit lines 216, word lines 218, source lines 214, SSG lines 215, and DSG lines 213. The peripheral circuits 202 can include any suitable analog, digital, and mixed-signal circuits for facilitating the operations of the memory array 201 by applying and sensing voltage signals and/or current signals to and from each target memory cell 206 through bit lines 216, word lines 218, source lines 214, SSG lines 215, and DSG lines 213. The peripheral circuits 202 can include various types of peripheral circuits formed using metal-oxide-semiconductor (MOS) technologies. The example peripheral circuits include a page buffer/sense amplifier 304, a column decoder/bit line driver 306, a row decoder/word line driver 308, a voltage generator 310, control logic 312, registers 314, an interface 316, and a data bus. In some examples, additional peripheral circuits not shown in FIG. 3 may be included as well.

The page buffer/sense amplifier 304 can be configured to read and program (write) data from and to memory array 201 according to the control signals from control logic 312. In an example, the page buffer/sense amplifier 304 may store one page of program data (write data) to be programmed into one page of the memory array 201. In another example, the page buffer/sense amplifier 304 may perform program verify operations to ensure that the data has been properly programmed into memory cells 206 coupled to selected word lines 218. In still another example, the page buffer/sense amplifier 304 may also sense the low power signals from the bit line 216 that represents a data bit stored in memory cell 206, and amplify the small voltage swing to recognizable logic levels in a read operation. The column decoder/bit line driver 306 can be configured to be controlled by the control logic 312 and select one or more NAND memory strings 208 by applying bit line voltages generated from the voltage generator 310.

The row decoder/word line driver 308 can be configured to be controlled by the control logic 312 and select/deselect blocks 204 of the memory array 201 and select/deselect word lines 218 of the block 204. The row decoder/word line driver 308 can be further configured to drive word lines 218 using word line voltages generated from the voltage generator 310. In some implementations, the row decoder/word line driver 308 can also select/deselect and drive SSG lines 215 and DSG lines 213. As described below in detail, the row decoder/word line driver 308 is configured to apply a program voltage to selected word line 218 in a program operation on memory cell 206 coupled to selected word line 218.

The voltage generator 310 can be configured to be controlled by the control logic 312 and generate the word line voltages (e.g., read voltage, program voltage, pass voltage, local voltage, verify voltage, etc.), bit line voltages, and source line voltages to be supplied to the memory array 201.

The control logic 312 can be coupled to each peripheral circuit described above and configured to control operations of each peripheral circuit. The registers 314 can be coupled to the control logic 312 and include status registers, command registers, and address registers for storing status information, command operation codes, and command addresses for controlling the operations of each peripheral circuit.

The interface 316 can be coupled to the control logic 312 and act as a control buffer to buffer and relay control commands received from a host (not shown) to the control logic 312 and status information received from the control logic 312 to the host. The interface 316 can also be coupled to the column decoder/bit line driver 306 via a data bus, and act as a data minput/output (I/O) interface and a data buffer to buffer and relay data to and from the memory array 201.

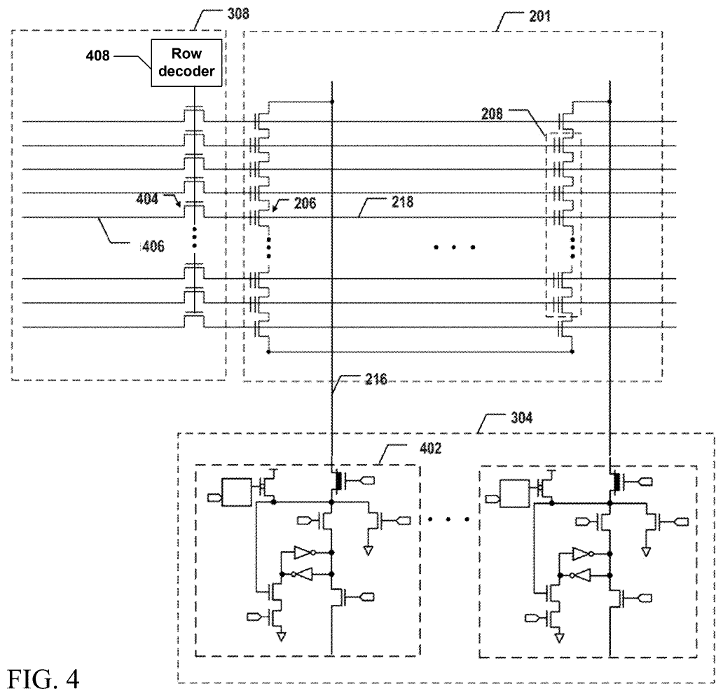

FIG. 4 illustrates schematic circuit diagrams of example word line driver 308 and page buffer 304 of FIG. 3, according to one or more implementations of the present disclosure. In some implementations, page buffer 304 can include a plurality of page buffer circuits 402 each coupled to one 3D NAND memory string 208 via a respective bit line 216. That is, memory device 200 can include bit lines 216 respectively coupled to 3D NAND memory strings 208, and page buffer 304 can include page buffer circuits 402 respectively coupled to bit lines 216 and 3D NAND memory strings 208. Each page buffer circuit 402 can include one or more latches, switches, supplies, nodes (e.g., data nodes and I/O nodes), current mirrors, verify logic, sense circuits, etc. In some implementations, each page buffer circuit 402 is configured to store sensing data received from a respective bit line 216, e.g., sensing current, corresponding to read data. Each page buffer circuit 402 can also be configured to output the stored sensing data to at the time of the read operation. Each page buffer circuit 402 can be further configured to store program data and output the stored program data to a respective bit line 216 at the time of the program operation.

In some implementations, word line driver includes a plurality of string drivers 404 (a.k.a. driving elements) respectively coupled to word lines 218. Word line driver 308 can also include a plurality of local word lines 406 (LWLs) respectively coupled to string drivers 404. Each string driver 404 can include a gate coupled to a row decoder 408, a source/drain coupled to a respective local word line 406, and another source/drain coupled to a respective word line 218. In some implementations, gates of two or more string drivers 404 are coupled to the same row decoder 408. For example, each memory block can have its corresponding row decoder 408. String drivers 404 coupled to word lines 218 in one memory block can be coupled to the same row decoder 408. In some memory operations, the row decoder 408 can select or unselect its corresponding memory block. For example, the row decoder 408 can apply a select voltage (e.g., a voltage higher than the threshold voltage of string drivers 404) on the gates of the string drivers 404 of the corresponding memory block, so that the corresponding memory block is selected. In contrast, the row decoder 408 can apply an unselect voltage (e.g., a voltage lower than the threshold voltage of string drivers 404) on the gates of the string drivers 404 of the corresponding memory block, so that the corresponding memory block is unselected. In some implementations, the peripheral circuits can include other circuits configured to select one or more particular string drivers 404 of the selected memory block, and apply a voltage (e.g., program voltage, pass voltage, or erase voltage) to each local word line 406, such that the voltage is applied by each selected string driver 404 to a respective word line 218.

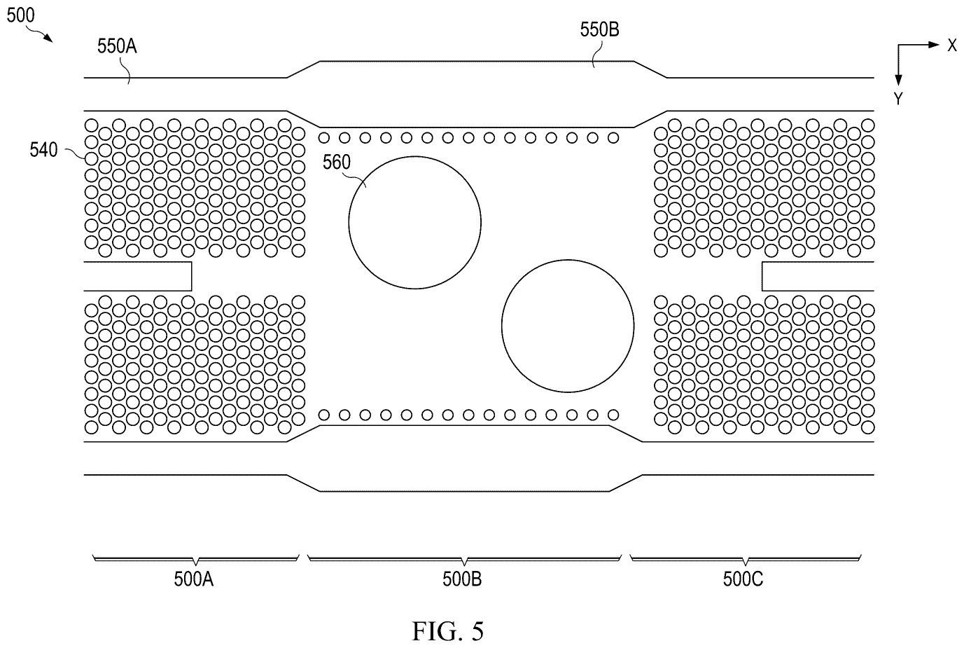

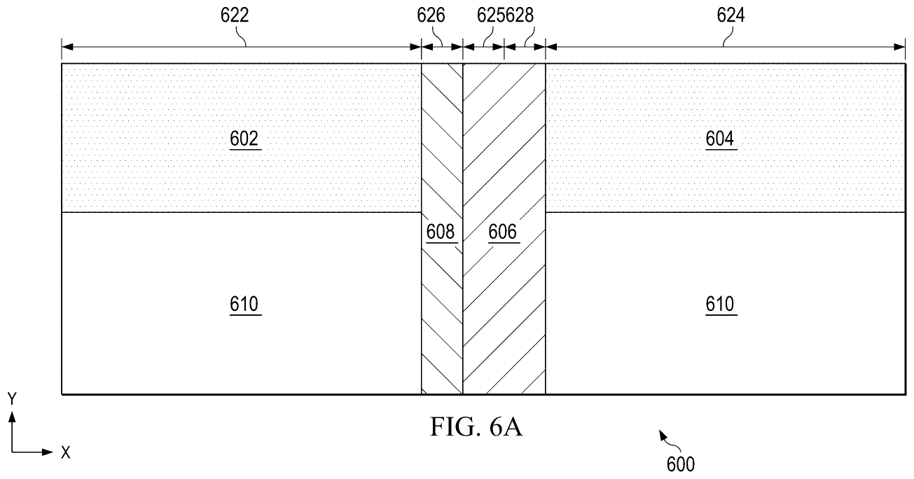

FIG. 5 illustrates a top view of an example first semiconductor structure 102, according to one or more implementations of the present disclosure. The first semiconductor structure 102 can be used to form a memory device, e.g., a 3D NAND memory device 200 of FIG. 2. In some implementations, the first semiconductor structure 102 includes one or more array regions and a connection region configured to provide conductive connections for the one or more array regions. In some examples, the first semiconductor structure 102 includes two array regions 500A, 500C and a connection region 500B between the two array regions along a first horizontal direction (e.g., X direction). Each array region 500A, 500C includes an array of channel structures 540. A channel structure 540 can be used to form a string of memory cells (e.g., memory string 208 of FIG. 2) that can be coupled in serial along a vertical direction (e.g., Z direction) perpendicular to the first horizontal direction. Contact structures 560 can be formed within the connection region 500B. A contact structure 560 can be configured to connect a corresponding one of the conductive layers within the array region 500A and/or array region 500C. A contact structure 560 can also be configured to connect a conductive layer of the first semiconductor structure 102 with a control circuit of the second semiconductor structure 104.

In some implementations, one or more first slit structures 550A can be formed within the array region 500A in the first horizontal direction (e.g., X direction) to divide the first semiconductor structure 102 into a plurality of memory blocks. Similarly, one or more second slit structures 550B can be formed in the connection region 500B in the first horizontal direction, to divide the first semiconductor structure 102 into the plurality of memory blocks. Corresponding first slit structure 550A and second slit structure 550B can be coupled to each other along the first horizontal direction (e.g., X direction). In some implementations, along the second horizontal direction (e.g., Y direction), a width of the first slit structure 550A is smaller than a width of the second slit structure 550B. For example, a width of the second slit structure 550B can be approximately 1.5 to 2 times that of the first slit structure 150A. In some implementations, a width of the first slit structure 550A is identical to a width of the second slit structure 550B. Each of the first slit structure(s) 550A and/or the second slit structure(s) 550B can extend in the vertical direction (e.g., Z direction) perpendicular to the first horizontal direction and the second horizontal direction.

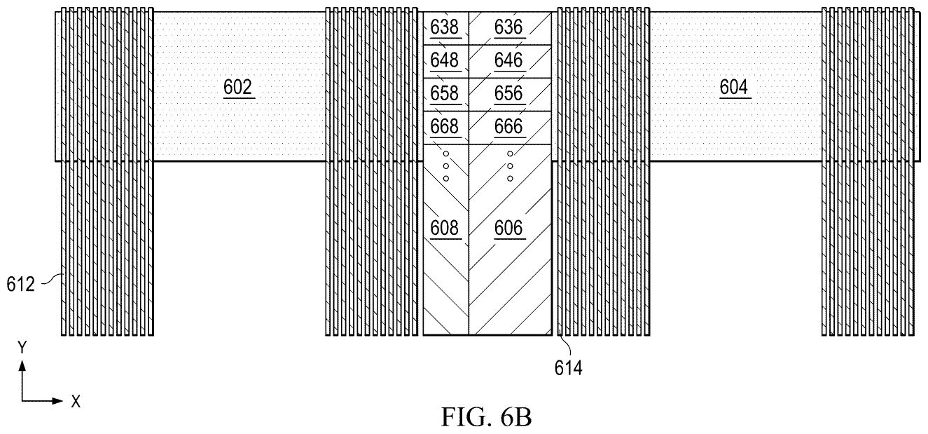

FIG. 6A illustrates a plan view (e.g., in the XY plane) of an example second semiconductor structure 600 (e.g., the second semiconductor structure 104 in FIGS. 1A and 1B), according to one or more implementations of the present disclosure. The second semiconductor structure 600 can include a first group of page buffers 602, a second group of page buffers 604, string drivers 606 and row decoders 608.

The first group of page buffers 602 can include page buffer circuits (e.g., page buffer circuits 402 of FIG. 4) each coupled to a bit line of a first memory array in a first array region (e.g., array region 500A of FIG. 5) of a first semiconductor structure such as the first semiconductor structure 102 of FIG. 1A or 1B. The second group of page buffers 604 can include page buffer circuits (e.g., page buffer circuits 402 of FIG. 4) each coupled to a bit line of a second memory array in a second array region (e.g., array region 500C of FIG. 5) of the first semiconductor structure 102. In some examples, the first memory array and the second memory array of the first semiconductor structure are both a memory array of 8K in width. That is, each of the first and second memory arrays has 8K memory cells along X direction. Accordingly, each of the first and second memory arrays has 8K bit lines distributed along X direction. In such case, the first group of page buffers 602 and the second group of page buffers 604 can each include 8K page buffer circuits. In some implementations, the bit lines in the first semiconductor structure 102 overlap with the corresponding page buffer circuits in the second semiconductor structure 104 in the plan view.

The string drivers 606 can include string drivers (e.g., string driver 404 of FIG. 4) each coupled to a word line in the first semiconductor structure 102. The row decoders 608 can include row decoders (e.g., row decoder 408 of FIG. 4) each coupled to a group of string drivers. The string drivers 606 and the row decoders 608 can be arranged between the first group of page buffers 602 and the second group of page buffers 604 along X direction. Remaining circuits 610 of the second semiconductor structure 600 can include column decoder/bit line driver 306, voltage generator 310, and other peripheral circuits.

In some implementations, a width (e.g., length along X direction) of the first group of page buffers 602 is equal to a width 622 of the first memory array of the first semiconductor structure 102. A width of the second group of page buffers 604 is equal to a width 624 of the second memory array of the first semiconductor structure 102. In other words, when the first semiconductor structure 102 and the second semiconductor structure 600 are stacked together along Z direction, in a plan view along Z direction, the first group of page buffers 602 overlaps with the first memory array of the first semiconductor structure 102, the second group of page buffers 604 overlaps with the second memory array of the first semiconductor structure 102, while the string driver 606 and the row decoders 608 do not overlap with the first memory array or the second memory array or are offset from the first memory array or the second memory array.

In some implementations, a width 625 of a connection region (e.g., connection region 500B of FIG. 5) between the first array region and the second array region in the first semiconductor structure 102 is less than a width of the string drivers 606 together with the row decoders 608. As such, the first semiconductor structure 102 has an unused region between the connection region and each of the array regions. For example, the unused region between the first array region and the connection region can have a width 626, and the unused region between the second array region and the connection region can have a width 628. In some implementations, the unused region does not include memory cells, which may limit the memory cell density of the first semiconductor structure 102. In some implementations, the unused region can include dummy memory cells that are not used for storing data.

FIG. 6B illustrates a plan view (e.g., in the XY plane) of an example 3D memory device (e.g., the 3D memory device 100 of FIG. 1A or the 3D memory device 101 of FIG. 1B) having the second semiconductor structure 600 of FIG. 6A, according to one or more implementations of the present disclosure. Bit lines of the memory array in the first array region of the first semiconductor structure 102 can be coupled to a corresponding page buffer circuit of the first group of page buffers 602 through first connection lines (not shown) and second connection lines 612. In some implementations, the first connection lines are located in the first semiconductor structure 102, and the second connection lines 612 are located in the second semiconductor structure 104. For example, a first connection line can connect a bit line with a first conductive structure in the first bonding layer of the first semiconductor structure 102. A second connection line 612 can connect a second conductive structure (e.g., a conductive structure in contact with the first conductive structure when the first semiconductor structure 102 and the second semiconductor structure 104 are stacked together) in the second bonding layer of the second semiconductor structure 104 with the corresponding page buffer circuit.

In some implementations, the second connection lines 612 are straight along Y direction and are spaced between each other along X direction. In some implementations, each of the second connection lines 612 overlaps with a corresponding page buffer circuit of the first group of page buffers 602 in the plan view. The second connection lines 612 do not overlap with (or are offset from) the string drivers 606 and the row decoders 608 in the plan view.

Similarly, bit lines of the memory array in the second array region can be coupled to corresponding page buffer circuits of the second group of page buffers 602 through first connection lines (not shown) in the first semiconductor structure 102, and second connection lines 614 in the second semiconductor structure 104. In some implementations, each of the second connection lines 614 overlaps with a corresponding page buffer circuit of the second group of page buffers 604 in the plan view.

In some implementations, the row decoders 608 are positioned on one side of the string drivers 606 along X direction. The row decoders 608 can include N row decoders that each correspond to one of N memory blocks in the first semiconductor structure 102 numbered from 0 to N-1, where N is an integer larger than 1. Each of the N row decoders is positioned adjacent to string drivers coupled to word lines in the corresponding memory block. For example, as shown in FIG. 6B, the string drivers 606 can include string drivers 636 coupled to word lines in the nth memory block in the first semiconductor structure 102, string drivers 646 coupled to word lines in the (n+1)^{th} memory block, string drivers 656 coupled to word lines in the (n+2)^{th} memory block, and string drivers 666 coupled to word lines in the (n+3)^{th} memory block. n is an integer. A row decoder 638 coupled to string drivers 636 is positioned adjacent to the string drivers 636. A row decoder 648 coupled to string drivers 646 is positioned adjacent to the string drivers 646. A row decoder 658 coupled to string drivers 656 is positioned adjacent to the string drivers 656. A row decoder 668 coupled to string drivers 666 is positioned adjacent to the string drivers 666.

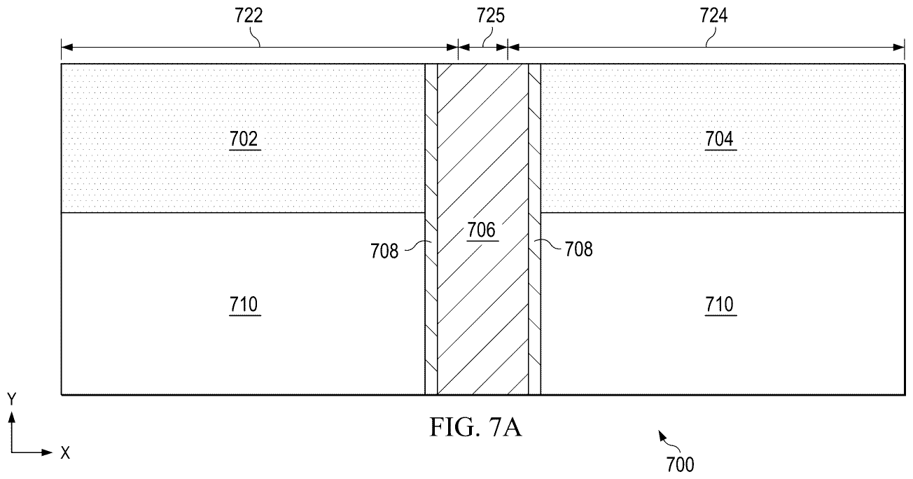

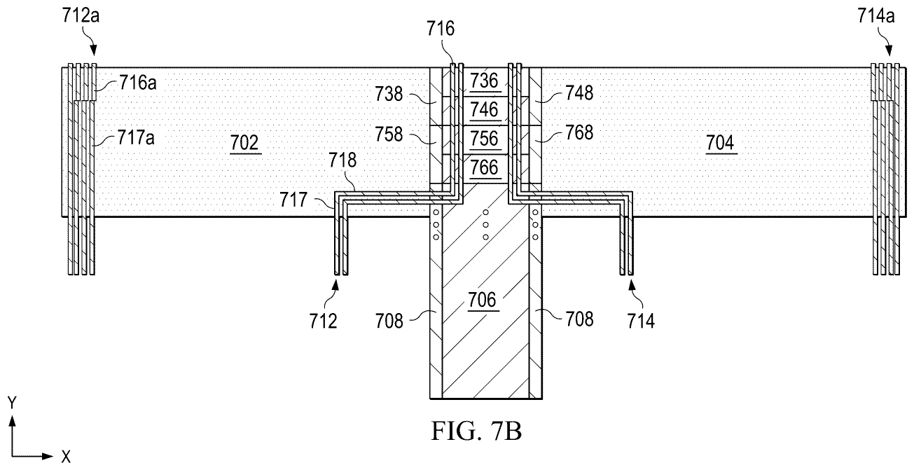

FIG. 7A illustrates a plan view (e.g., in the XY plane) of an example second semiconductor structure 700 (e.g., the second semiconductor structure 104 in FIG. 1A or 1B), according to one or more implementations of the present disclosure. The second semiconductor structure 700 can include a first group of page buffers 702, a second group of page buffers 704, string drivers 706 and row decoders 708.

The first group of page buffers 702 can include page buffer circuits (e.g., page buffer circuits 402 of FIG. 4) each coupled to a bit line of a first memory array in a first array region (e.g., array region 500A of FIG. 5) of the first semiconductor structure 102. The second group of page buffers 604 can include page buffer circuits (e.g., page buffer circuits 402 of FIG. 4) each coupled to a bit line of a second memory array in a second array region (e.g., array region 500C of FIG. 5) of the first semiconductor structure 102. In some examples, the first memory array and the second memory array of the first semiconductor structure 102 are both a memory array of 8K in width. That is, the first and second memory arrays each have 8K memory cells along X direction. Accordingly, the first and second memory arrays each have 8K bit lines distributed along X direction. In such case, the first group of page buffers 702 and the second group of page buffers 704 can each include 8K page buffer circuits. In some implementations, at least a portion of the bit lines in the first semiconductor structure 102 are distanced from the corresponding page buffer circuits of the first and second groups of page buffers 702, 704 along X direction in the plan view.

The string drivers 706 can include string drivers (e.g., string driver 404 of FIG. 4) each coupled to a word line in the first semiconductor structure 102. The row decoders 708 can include row decoders (e.g., row decoder 408 of FIG. 4) each coupled to a group of string drivers. The string drivers 706 and the row decoders 708 can be arranged between the first group of page buffers 702 and the second group of page buffers 704 along X direction. In some implementations, the row decoders 708 can include a first group of row decoders positioned on one side of the string drivers 706, and a second group of row decoders positioned on the other side of the string drivers 706. Remaining circuits 710 of the second semiconductor structure 700 can include column decoder/bit line driver 306, voltage generator 310, and other peripheral circuits.

In some implementations, a width (e.g., length along X direction) of the first group of page buffers 702 is less than a width 722 of the first memory array of the first semiconductor structure 102. A width of the second group of page buffers 704 is less than a width 724 of the second memory array of the first semiconductor structure 102. A width 725 of a connection region (e.g., connection region 500B of FIG. 5) between the first array region and the second array region in the first semiconductor structure 102 is less than a width of the string driver 706 together with the row decoders 708. A sum of the width 722, the width 724 and the width 725 is equal to or substantially identical to a sum of the width of first group of page buffers 702, the width of the second group of page buffers 704, the width of the string drivers 706 and the width of the row decoders 708. As used herein, the term “substantially” is intended to accommodate manufacturing tolerances. In other words, when the first semiconductor structure 102 and the second semiconductor structure 700 are stacked together along Z direction, in a plan view along Z direction, the first group of page buffers 702 overlaps with the first memory array of the first semiconductor structure 102, the second group of page buffers 704 overlaps with the second memory array of the first semiconductor structure 102, while at least one of the string drivers 706 or the row decoders 708 at least partially overlap with the first memory array or the second memory array of the first semiconductor structure 102. In some implementations, all of the row decoders 708 and a first part of the string drivers 706 overlap with the first memory array or the second memory array. A second part of the string drivers overlap with the connection region. As such, there can be no unused region between the connection region and either of the first and second array regions, therefore a memory cell density of the first semiconductor structure 102 can be increased.

FIG. 7B illustrates a plan view (e.g., in the XY plane) of an example 3D memory device (e.g., 100 of FIG. 1A or 101 of FIG. 1B) having the second semiconductor structure 700, according to one or more implementations of the present disclosure.

In some implementations, bit lines of the memory array in the first array region of the first semiconductor structure 102 can be coupled to corresponding page buffer circuit of the first group of page buffers 702 through first connection lines (not shown) and second connection lines 712, 712a. The first connection lines are located in the first semiconductor structure 102, and the second connection lines 712, 712a are located in the second semiconductor structure 104. For example, a first connection line can connect a bit line with a first conductive structure in the first bonding layer of the first semiconductor structure 102. A second connection line 712, 712a can connect a second conductive structure (e.g., a conductive structure in contact with the first conductive structure when the first semiconductor structure 102 and the second semiconductor structure 104 are stacked together) in the second bonding layer of the second semiconductor structure 104 with the corresponding page buffer circuit. In some implementations, different from the second connection lines 612 in FIG. 6B where the second connection lines 612 are straight lines, the second connection lines 712, 712a can have multiple parts that are offset from one another. In some implementations, a second connection line 712 can include a first part 716 and a second part 717 both extending along Y direction, and a third part 718 connecting ends of the first part 716 and the second part 717. The first part 716 and the second part 717 are distanced from each other along X direction. For example, the first part 716 of the second connection line 712 can overlap with one of the string drivers 706 or the row decoders 708 in the plan view. The second part 717 of the second connection line 712 can overlap with a corresponding page buffer circuit of the first group of page buffers 702 in the plan view. In some implementations, along the X direction, from the first array region to the connection region, the offset between the first part 716 and the second part 717 becomes greater and greater, or a length of the third part 718 along X direction becomes greater and greater, e.g., as illustrated in FIG. 7B. For example, a second connection line 712a is positioned further from the string drivers 706 and the row decoders 708 than the second connection line 712. The second connection line 712a includes a first part 716a and a second part 717a both extending along Y direction. The offset between the first part 716a and the second part 717a along X direction is smaller than the offset between the first part 716 and the second part 717 along X direction.

In some implementations, bit lines of the memory array in the second array region of the first semiconductor structure 102 can be coupled to a corresponding page buffer circuit of the second group of page buffers 704 through first connection lines (not shown) in the first semiconductor structure 102 and second connection lines 714, 714a in the second semiconductor structure 104. In some implementations, the second connection lines 714, 714a can have multiple parts that are offset from one another, similar to second connection lines 712, 712a.

In such a way, the second connection lines 712, 712a, 714, 714a can utilize a larger space than the first and second groups of page buffers 702 and 704 in the second semiconductor structure 104, without causing unused regions in the first semiconductor structure 104. Therefore, the sizes of the first and second semiconductor structure 102, 104 can be reduced along X direction.

In some implementations, the row decoders 708 can include N row decoders that each correspond to one of N memory blocks in the first semiconductor structure 102 numbered from 0 to N-1. The row decoders 708 can include two groups of row decoders each positioned on one side of the string drivers 706 along X direction, e.g., as illustrated in FIG. 7A or FIG. 7B. In some implementations, the row decoders 708 are symmetrically positioned on both sides of the string drivers 706. For example, row decoders associated with an even-numbered memory block can be positioned on a first side of the string drivers 706, and row decoders associated with an odd-numbered memory block can be positioned on a second side of the string drivers 706. As shown in FIG. 7B, the string drivers 706 can include string drivers 736 coupled to word lines in the nth memory block in the first semiconductor structure 102, string drivers 746 coupled to word lines in the (n+1)^{th} memory block, string drivers 756 coupled to word lines in the (n+2)^{th} memory block, and string drivers 766 coupled to word lines in the (n+3)^{th} memory block. A row decoder 738 coupled to string drivers 736 is positioned on the first side of the string drivers 736. A row decoder 748 coupled to string drivers 746 is positioned on the second side of the string drivers 746. A row decoder 758 coupled to string drivers 756 is positioned on the first side of the string drivers 756. A row decoder 768 coupled to string drivers 766 is positioned on the second side of the string drivers 766. In some implementations, a length (e.g., length along Y direction) of the row decoder 738 is less than or equal to twice a length of the string drivers 736.

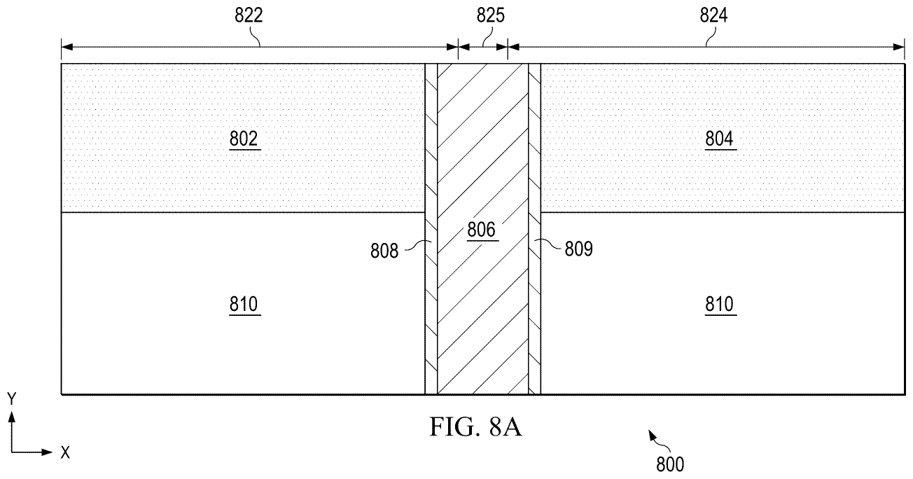

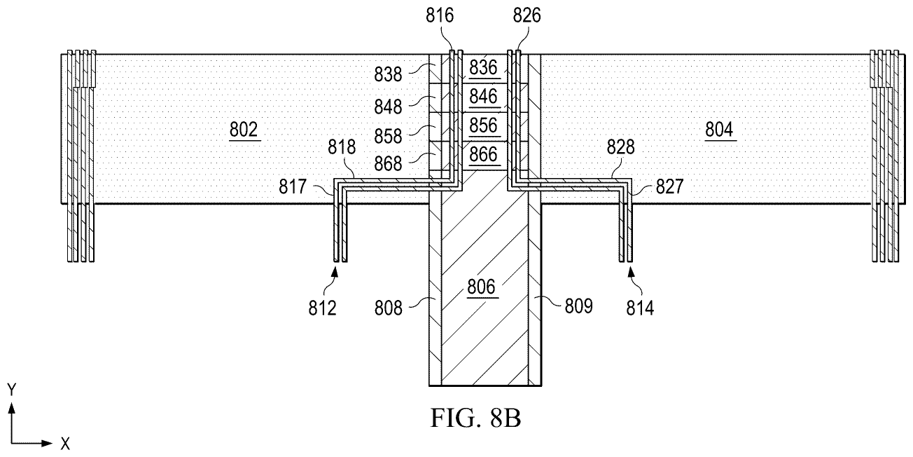

FIG. 8A illustrates a plan view (e.g., in the XY plane) of an example second semiconductor structure 800 (e.g., the second semiconductor structure 104 in FIG. 1A or 1B), according to one or more implementations of the present disclosure. The second semiconductor structure 800 can include a first group of page buffers 802, a second group of page buffers 804, string drivers 806 and row decoders 808.

The first group of page buffers 802 can include page buffer circuits (e.g., page buffer circuits 402 of FIG. 4) each coupled to a bit line of a first memory array in a first array region (e.g., array region 500A of FIG. 5) of the first semiconductor structure 102. The second group of page buffers 604 can include page buffer circuits (e.g., page buffer circuits 402 of FIG. 4) each coupled to a bit line of a second memory array in a second array region (e.g., array region 500C of FIG. 5) of the first semiconductor structure 102. In some examples, the first memory array and the second memory array of the first semiconductor structure 102 are both a memory array of 8K in width. That is, the first and second memory arrays each have 8K memory cells along X direction. Accordingly, the first and second memory arrays each have 8K bit lines distributed along X direction. In such case, the first group of page buffers 802 and the second group of page buffers 804 can each include 8K page buffer circuits. In some implementations, at least a portion of the bit lines in the first semiconductor structure 102 are distanced from the corresponding page buffer circuits of the first and second groups of page buffers 802, 804 along X direction in the plan view.

The string drivers 806 can include string drivers (e.g., string driver 404 of FIG. 4) each coupled to a word line in the first semiconductor structure 102. The row decoders 808 can include row decoders (e.g., row decoder 408 of FIG. 4) each coupled to a group of string drivers. The string drivers 806 and the row decoders 808 can be arranged between the first group of page buffers 802 and the second group of page buffers 804 along X direction. Remaining circuits 809, 810 of the second semiconductor structure 800 can include column decoder/bit line driver 306, voltage generator 310, and other peripheral circuits. In some implementations, the row decoders 808 are positioned on one side of the string drivers 806, and the remaining circuits 809 are positioned on the other side of the string driver 806. The remaining circuits 809 can include driver circuits related to page buffers.

In some implementations, a width (e.g., length along X direction) of the first group of page buffers 802 is less than a width 822 of the first memory array of the first semiconductor structure 102. A width of the second group of page buffers 804 is less than a width 824 of the second memory array of the first semiconductor structure 102. A width 825 of a connection region (e.g., connection region 500B of FIG. 5) between the first array region and the second array region in the first semiconductor structure 102 is less than a width of the string driver 806, the row decoders 808 together with the remaining circuits 809. A sum of the width 822, the width 824 and the width 825 is equal to a sum of the width of first group of page buffers 802, the width the second group of page buffers 804, the width of the string drivers 806, the width of the row decoders 808 and the width of the remaining circuits 809. In other words, when the first semiconductor structure 102 and the second semiconductor structure 800 are stacked together along Z direction, in a plan view along Z direction, the first group of page buffers 802 overlaps with the first memory array of the first semiconductor structure 102, the second group of page buffers 804 overlaps with the second memory array of the first semiconductor structure 102, while at least one of the string driver 806 or the row decoders 808 at least partially overlap with the first memory array or the second memory array of the first semiconductor structure 102. In some implementations, all of the row decoders 808, all of the remaining circuits 809 and a first part of the string drivers 806 overlap with the first memory array or the second memory array. A second part of the string drivers 706 overlap with the connection region. As such, there can be no unused region between the connection region and either of the array regions, therefore memory cell density of the first semiconductor structure 102 can be increased.

FIG. 8B illustrates a plan view (e.g., in the XY plane) of an example 3D memory device 100, 101 having second semiconductor structure 800, according to one or more implementations of the present disclosure.

In some implementations, bit lines of the memory array in the first array region of the first semiconductor structure 102 can be coupled to corresponding page buffer circuit of the first group of page buffers 802 through first connection lines (not shown) and second connection lines 812. The first connection lines are located in the first semiconductor structure 102, and the second connection lines 812 are located in the second semiconductor structure 104. For example, a first connection line can connect a bit line with a first conductive structure in the first bonding layer of the first semiconductor structure 102. A second connection line 712, 712a can connect a second conductive structure (e.g., a conductive structure in contact with the first conductive structure when the first semiconductor structure 102 and the second semiconductor structure 104 are stacked together) in the second bonding layer of the second semiconductor structure 104 with the corresponding page buffer circuit. In some implementations, similar to second connection lines 712, 712a of FIG. 7B, the second connection lines 812 can have multiple parts that are offset from one another. In some implementations, a second connection line 812 can include a first part 816 and a second part 817 both extending along Y direction, and a third part 818 connecting ends of the first part 816 and the second part 817. The first part 816 and the second part 817 are distanced from each other along X direction. For example, the first part 816 of the second connection line 812 can overlap with one of the string drivers 806 or the row decoders 808 in the plan view. The second part 817 of the second connection line 812 can overlap with a corresponding page buffer circuit of the first group of page buffers 802 in the plan view. In some implementations, along the X direction, from the first array region to the connection region, the offset between the first part 816 and the second part 817 becomes greater and greater, or a length of the third part 818 along X direction becomes greater and greater, e.g., as illustrated in FIG. 8B.

In some implementations, bit lines of the memory array in the second array region of the first semiconductor structure 102 can be coupled to corresponding page buffer circuit of the second group of page buffers 804 through first connection lines (not shown) in the first semiconductor structure 102 and second connection lines 814 in the second semiconductor structure 104. In some implementations, the second connection lines 814 can have multiple parts that are offset from one another, similar to second connection lines 812. For example, the second connection line 814 can include a first part 826 overlapping with one of the string drivers 806 or the remaining circuits 809, a second part 827 overlapping with the corresponding page buffer circuits of the second group of page buffers 804, and a third part 828 connecting ends of the first part 826 and the second part 827.

In some implementations, the row decoders 808 are positioned on one side of the string drivers 806 along X direction. The row decoders 808 can include N row decoders that each correspond to one of N memory blocks in the first semiconductor structure 102 numbered from 0 to N-1. Each of the N row decoders is positioned adjacent to string drivers coupled to word lines in the corresponding memory block. For example, as shown in FIG. 8B, the string drivers 806 can include string drivers 836 coupled to word lines in the nth memory block in the first semiconductor structure 102, string drivers 846 coupled to word lines in the (n+1)^{th} memory block, string drivers 856 coupled to word lines in the (n+2)^{th} memory block, and string drivers 866 coupled to word lines in the (n+3)^{th} memory block. A row decoder 838 coupled to string drivers 836 is positioned on a first side of the string drivers 836. A row decoder 848 coupled to string drivers 846 is positioned on the first side of the string drivers 846. A row decoder 858 coupled to string drivers 856 is positioned on the first side of the string drivers 856. A row decoder 868 coupled to string drivers 866 is positioned on the first side of the string drivers 866.

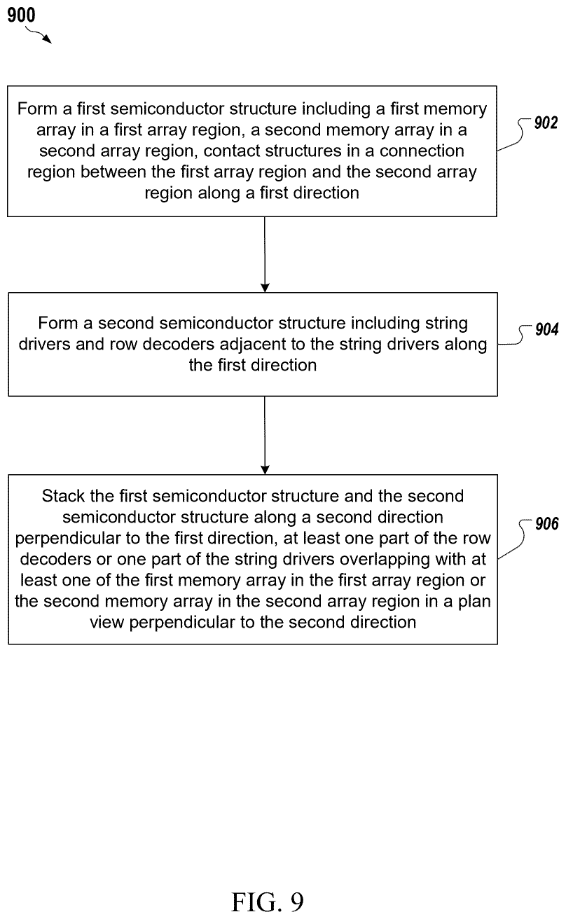

FIG. 9 is a flow chart of an example process 900 of forming a memory device. The memory device can be the 3D memory device 100 of FIG. 1A, or the 3D memory device 101 of FIG. 1B. The process 900 includes operations (or steps) that can be performed with any suitable order and/or any combination.

At operation 902, a first semiconductor structure (e.g., the first semiconductor structure 102 of FIG. 1A or 1B, or the first semiconductor 500 of FIG. 5) is formed. The first semiconductor structure includes a first memory array in a first array region (e.g., the array region 500A of FIG. 5), a second memory array in a second array region (e.g., the array region 500C of FIG. 5), contact structures in a connection region (e.g., the connection region 500B of FIG. 5). The connection region is positioned between the first array region and the second array region along a first direction (e.g., X direction). The first memory array and the second memory array can each be the memory array 201 of FIG. 2 that includes NAND memory cells.

At operation 904, a second semiconductor structure (e.g., the second semiconductor structure 104 of FIGS. 1A-1B, the second semiconductor structure 600 of FIG. 6A, the second semiconductor structure 700 of FIG. 7A, or the second semiconductor structure 800 of FIG. 8A) is formed. The second semiconductor structure includes string drivers (e.g., the string drivers 404 in FIG. 4, the string drivers 606 in FIGS. 6A-6B, the string drivers 706 in FIGS. 7A-7B, or the string drivers 806 in FIGS. 8A-8B). The second semiconductor structure further includes row decoders (e.g., the row decoder 408 in FIG. 4, the row decoders 608 in FIGS. 6A-6B, the row decoders 708 in FIGS. 7A-7B, or the row decoders 808 in FIGS. 8A-8B) positioned adjacent to the string drivers along the first direction.

In some implementations, e.g., as illustrated in FIGS. 6A-6B, 8A-8B, the row decoders are positioned on one side of the string drivers. In some implementations, e.g., as illustrated in FIGS. 7A-7B, the row decoders include a first group of row decoders positioned on a first side of the string drivers, and a second group of row decoders positioned on a second side of the string drivers. For example, the first semiconductor structure can include N memory block numbered from 0 to N-1. A row decoder (e.g., the row decoders 738, 758) coupled to string drivers that are coupled to word lines in a memory block associated with an even number can be positioned on the first side of the string drivers. A row decoder (e.g., the row decoders 748, 768) coupled to string drivers that are coupled to word lines in a memory block associated with an odd number can be positioned on the second side of the string drivers.

At operation 906, the first semiconductor structure and the second semiconductor structure are stacked together along a second direction (e.g., Z direction) perpendicular to the first direction. At least one part of the row decoders or one part of the string drivers overlap with at least one of the first memory array or the second memory array in a plan view (e.g., XY plane) perpendicular to the second direction. In some implementations, e.g., as illustrated in FIGS. 7A-7B, 8A-8B, all of the row decoders and a first part of the string drivers overlap with the first memory array and/or the second memory array in the plan view. A second part of the string drivers overlap with the connection area in the plan view.

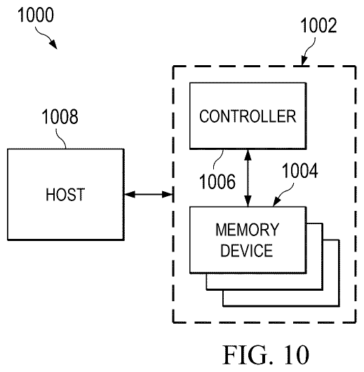

FIG. 10 illustrates a block diagram of a system 1000 having one or more semiconductor devices (e.g., memory devices), according to one or more implementations of the present disclosure. The system 1000 can be a mobile phone, a desktop computer, a laptop computer, a tablet, a vehicle computer, a gaming console, a printer, a positioning device, a wearable electronic device, a smart sensor, a virtual reality (VR) device, an argument reality (AR) device, or any other suitable electronic devices having storage therein. As shown in FIG. 10, the system 1000 can include a host device 1008 and a memory system 1002 having one or more 3D memory devices 1004 and a memory controller 1006. Host device 1008 can include a processor of an electronic device, such as a central processing unit (CPU), or a system-on-chip (SoC), such as an application processor (AP). Host device 1008 can be configured to send or receive data to or from the one or more 3D memory devices 1004.

A 3D memory device 1004 can be any 3D memory device disclosed herein, such as 3D memory device depicted in any one of FIGS. 1-9. In some implementations, a 3D memory device 1004 includes a NAND Flash memory. Memory controller 1006 (a.k.a., a controller circuit) is coupled to 3D memory device 1004 and host device 1008. Consistent with implementations of the present disclosure, 3D memory device 1004 can include a plurality of conductive interconnections through a cover layer that are in contact with conductive pads in a conductive pad layer, and memory controller 1006 can be coupled to 3D memory device 1004 through at least one of the plurality of conductive interconnections. Memory controller 1006 is configured to control 3D memory device 1004. For example, memory controller 1006 may be configured to operate a plurality of channel structures via word lines. Memory controller 1006 can manage data stored in 3D memory device 1004 and communicate with host device 1008.

In some implementations, memory controller 1006 is designed/configured for operating in a low duty-cycle environment like secure digital (SD) cards, compact Flash (CF) cards, universal serial bus (USB) Flash drives, or other media for use in electronic devices, such as personal computers, digital cameras, mobile phones, etc. In some implementations, memory controller 1006 is designed/configured for operating in a high duty cycle environment SSDs or embedded multi-media-cards (eMMCs) used as data storage for mobile devices, such as smartphones, tablets, laptop computers, etc., and enterprise storage arrays. Memory controller 1006 can be configured to control operations of 3D memory device 1004, such as read, erase, and program (or write) operations. Memory controller 1006 can also be configured to manage various functions with respect to the data stored or to be stored in 3D memory device 1004 including, but not limited to bad-block management, garbage collection, logical-to-physical address conversion, wear leveling, etc. In some implementations, memory controller 1006 is further configured to process error correction codes (ECCs) with respect to the data read from or written to 3D memory device 1004. Any other suitable functions may be performed by memory controller 1006 as well, for example, formatting 3D memory device 1004.

Memory controller 1006 can communicate with an external device (e.g., host device 1008) according to a particular communication protocol. For example, memory controller 1006 may communicate with the external device through at least one of various interface protocols, such as a USB protocol, an MMC protocol, a peripheral component interconnection (PCI) protocol, a PCIexpress (PCI-E) protocol, an advanced technology attachment (ATA) protocol, a serial-ATA protocol, a parallel-ATA protocol, a small computer small interface (SCSI) protocol, an enhanced small disk interface (ESDI) protocol, an integrated drive electronics (IDE) protocol, a Firewire protocol, etc.

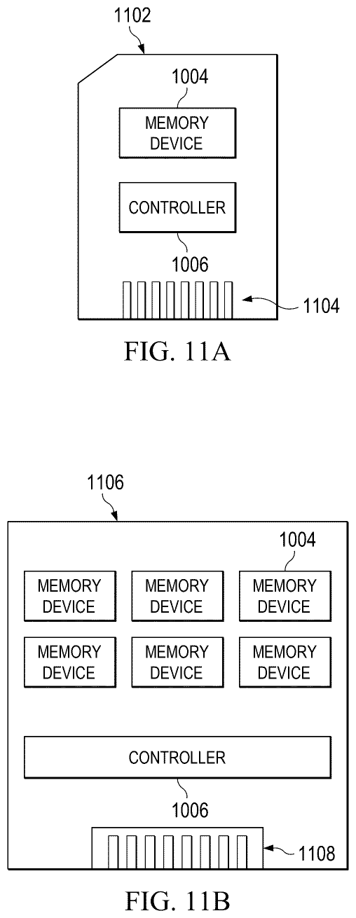

Memory controller 1006 and one or more 3D memory devices 1004 can be integrated into various types of storage devices, for example, be included in the same package, such as a universal Flash storage (UFS) package or an eMMC package. In one example as shown in FIG. 11A, memory controller 1006 and a single memory device 1004 may be integrated into a memory card 1102. Memory card 1102 can include a PC card (PCMCIA, personal computer memory card international association), a CF card, a smart media (SM) card, a memory stick, a multimedia card (MMC, RS-MMC, MMCmicro), an SD card (SD, miniSD, microSD, SDHC), a UFS, etc. Memory card 1102 can further include a memory card connector 1104 coupling memory card 1102 with a host (e.g., host 1008 of FIG. 10). In another example as shown in FIG. 11B, memory controller 1006 and multiple memory devices 1004 may be integrated into an SSD 1106. SSD 1106 can further include an SSD connector 1108 coupling SSD 1106 with a host (e.g., host 1008 of FIG. 10). In some implementations, the storage capacity and/or the operation speed of SSD 1106 is greater than those of memory card 1102.

Implementations of the subject matter and the actions and operations described in this present disclosure can be implemented in digital electronic circuitry, in tangibly-embodied computer software or firmware, in computer hardware, including the structures disclosed in this present disclosure and their structural equivalents, or in combinations of one or more of them. Implementations of the subject matter described in this present disclosure can be implemented as one or more computer programs, e.g., one or more modules of computer program instructions, encoded on a computer program carrier, for execution by, or to control the operation of, data processing apparatus. The carrier may be a tangible non-transitory computer storage medium. Alternatively, or in addition, the carrier may be an artificially-generated propagated signal, e.g., a machine-generated electrical, optical, or electromagnetic signal, that is generated to encode information for transmission to suitable receiver apparatus for execution by a data processing apparatus. The computer storage medium can be or be part of a machine-readable storage device, a machine-readable storage substrate, a random or serial access memory device, or a combination of one or more of them. A computer storage medium is not a propagated signal.

It is noted that references in the present disclosure to “one embodiment,” “an embodiment,” “an example embodiment,” “some implementations,” “some implementations,” etc., indicate that the embodiment described can include a particular feature, structure, or characteristic, but every embodiment can not necessarily include the particular feature, structure, or characteristic. Moreover, such phrases do not necessarily refer to the same embodiment. Further, when a particular feature, structure or characteristic is described in connection with an embodiment, it would be within the knowledge of a person skilled in the pertinent art to affect such feature, structure or characteristic in connection with other implementations whether or not explicitly described.

In general, terminology can be understood at least in part from usage in context. For example, the term “one or more” as used herein, depending at least in part upon context, can be used to describe any feature, structure, or characteristic in a singular sense or can be used to describe combinations of features, structures or characteristics in a plural sense. Similarly, terms, such as “a,” “an,” or “the,” again, can be understood to convey a singular usage or to convey a plural usage, depending at least in part upon context. In addition, the term “based on” can be understood as not necessarily intended to convey an exclusive set of factors and may, instead, allow for existence of additional factors not necessarily expressly described, again, depending at least in part on context.

It should be readily understood that the meaning of “on,” “above,” and “over” in the present disclosure should be interpreted in the broadest manner such that “on” not only means “directly on” something, but also includes the meaning of “on” something with an intermediate feature or a layer therebetween. Moreover, “above” or “over” not only means “above” or “over” something, but can also include the meaning it is “above” or “over” something with no intermediate feature or layer therebetween (i.e., directly on something).

Further, spatially relative terms, such as “beneath,” “below,” “lower,” “above,” “upper,” and the like, can be used herein for ease of description to describe one element or feature's relationship to another element(s) or feature(s) as illustrated in the figures. The spatially relative terms are intended to encompass different orientations of the device in use or process step in addition to the orientation depicted in the figures. The apparatus can be otherwise oriented (rotated 90 degrees or at other orientations) and the spatially relative descriptors used herein can likewise be interpreted accordingly.

As used herein, the term “substrate” refers to a material onto which subsequent material layers are added. The substrate includes a “top” surface and a “bottom” surface. The top surface of the substrate is typically where a semiconductor device is formed, and therefore the semiconductor device is formed at a top side of the substrate unless stated otherwise. The bottom surface is opposite to the top surface and therefore a bottom side of the substrate is opposite to the top side of the substrate. The substrate itself can be patterned. Materials added on top of the substrate can be patterned or can remain unpatterned. Furthermore, the substrate can include a wide array of semiconductor materials, such as silicon, germanium, gallium arsenide, indium phosphide, etc. Alternatively, the substrate can be made from an electrically non-conductive material, such as a glass, a plastic, or a sapphire wafer.

As used herein, the term “layer” refers to a material portion including a region with a thickness. A layer has a top side and a bottom side where the bottom side of the layer is relatively close to the substrate and the top side is relatively away from the substrate. A layer can extend over the entirety of an underlying or overlying structure, or can have an extent less than the extent of an underlying or overlying structure. Further, a layer can be a region of a homogeneous or inhomogeneous continuous structure that has a thickness less than the thickness of the continuous structure. For example, a layer can be located between any set of horizontal planes between, or at, a top surface and a bottom surface of the continuous structure. A layer can extend horizontally, vertically, and/or along a tapered surface. A substrate can be a layer, can include one or more layers therein, and/or can have one or more layer thereupon, thereabove, and/or therebelow. A layer can include multiple layers. For example, an interconnect layer can include one or more conductive and contact layers (in which contacts, interconnect lines, and/or vertical interconnect accesses (VIAs) are formed) and one or more dielectric layers.

As used herein, the term “nominal/nominally” refers to a desired, or target, value of a characteristic or parameter for a component or a process step, set during the design phase of a product or a process, together with a range of values above and/or below the desired value. As used herein, the range of values can be due to slight variations in manufacturing processes or tolerances. As used herein, the term “about” indicates the value of a given quantity that can vary based on a particular technology node associated with the subject semiconductor device. Based on the particular technology node, the term “about” can indicate a value of a given quantity that varies within, for example, 10-30% of the value (e.g., .+−.10%, .+−.20%, or .+−.30% of the value).

In the present disclosure, the term “horizontal/horizontally/lateral/laterally” means nominally parallel to a lateral surface of a substrate, and the term “vertical” or “vertically” means nominally perpendicular to the lateral surface of a substrate. The terms “operation” and “step” can be used interchangeably to describe a process.

As used herein, the term “3D memory” refers to a three-dimensional (3D) semiconductor device with vertically oriented strings of memory cell transistors (referred to herein as “memory strings,” such as NAND strings) on a laterally-oriented substrate so that the memory strings extend in the vertical direction with respect to the substrate.

The present disclosure provides many different implementations, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include implementations in which the first and second features may be in direct contact, and may also include implementations in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various implementations and/or configurations discussed.

The foregoing description of the specific implementations can be readily modified and/or adapted for various applications. Therefore, such adaptations and modifications are intended to be within the meaning and range of equivalents of the disclosed implementations, based on the teaching and guidance presented herein.

While the present disclosure contains many specific implementation details, these should not be construed as limitations on the scope of what is being claimed, which is defined by the claims themselves, but rather as descriptions of features that may be specific to particular implementations. Certain features that are described in this present disclosure in the context of separate implementations can also be implemented in combination in a single implementation. Conversely, various features that are described in the context of a single implementation can also be implemented in multiple implementations separately or in any suitable sub-combination. Moreover, although features may be described above as acting in certain combinations and even initially be claimed as such, one or more features from a claimed combination can in some cases be excised from the combination, and the claim may be directed to a sub-combination or variation of a sub-combination.

Similarly, while operations are depicted in the drawings and recited in the claims in a particular order, this should not be understood as requiring that such operations be performed in the particular order shown or in sequential order, or that all illustrated operations be performed, to achieve desirable results. In certain circumstances, multitasking and parallel processing may be advantageous. Moreover, the separation of various system modules and components in the implementations described above should not be understood as requiring such separation in all implementations, and it should be understood that the described program components and systems can generally be integrated together in a single software product or packaged into multiple software products.

Particular implementations of the subject matter have been described. Other implementations also are within the scope of the following claims. For example, the actions recited in the claims can be performed in a different order and still achieve desirable results. As one example, the processes depicted in the accompanying figures do not necessarily require the particular order shown, or sequential order, to achieve desirable results. In some cases, multitasking and parallel processing may be advantageous.

The breadth and scope of the present disclosure should not be limited by any of the above-described exemplary implementations, but should be defined only in accordance with the following claims and their equivalents.

What is claimed is:

1. A memory device, comprising:
a first semiconductor structure comprising a first memory array in a first array region, a second memory array in a second array region, contact structures in a connection region between the first array region and the second array region along a first direction, and word lines coupled to memory cells in the first memory array and memory cells in the second memory array; and
a second semiconductor structure comprising row decoders,
wherein the first semiconductor structure and the second semiconductor structure are stacked together along a second direction perpendicular to the first direction, and
wherein at least one part of the row decoders overlaps with at least one of the first memory array in the first array region or the second memory array in the second array region in a plan view perpendicular to the second direction.

2. The memory device of claim 1, wherein the second semiconductor structure further comprises string drivers, wherein a string driver of the string drivers is coupled to a corresponding word line through a contact structure in the connection region and coupled to a corresponding row decoder, and wherein at least a first part of the string drivers overlaps with the at least one of the first memory array in the first array region or the second memory array in the second array region in the plan view.

3. The memory device of claim 2, wherein a second part of the string drivers overlaps with the contact structures in the connection region in the plan view.

4. The memory device of claim 2, wherein the row decoders are positioned adjacent to the string drivers along the first direction.

5. The memory device of claim 4, wherein the row decoders are positioned on one side of the string drivers.

6. The memory device of claim 4, wherein the row decoders comprise:
a first group of row decoders positioned on a first side of the string drivers; and
a second group of row decoders positioned on a second side of the string drivers.

7. The memory device of claim 6, wherein the first semiconductor structure comprises N memory blocks numbered from 0 to N-1,
wherein the first group of row decoders comprises a first row decoder coupled to first string drivers that are coupled to word lines in a first memory block associated with an odd number, and
wherein the second group of row decoders comprises a second row decoder coupled to second string drivers that are coupled to word lines in a second memory block associated with an even number.

8. The memory device of claim 7, wherein the first string drivers and the second string drivers are between the first row decoder and the second row decoder along the first direction, and wherein the odd number and the even number are adjacent integers.

9. The memory device of claim 2, wherein the second semiconductor structure further comprises a first group of page buffers and a second group of page buffers, and
wherein the row decoders and the string drivers are positioned between the first group of page buffers and the second group of page buffers along the first direction.

10. The memory device of claim 9, wherein the first semiconductor structure further comprises bit lines coupled to the memory cells in the first memory array, wherein the bit lines are coupled to corresponding page buffers of the first group of page buffers, and wherein at least a first part of one of the bit lines is distanced from a corresponding page buffer along the first direction in the plan view.

11. The memory device of claim 10, wherein the one of the bit lines is coupled to the corresponding page buffer through a first connection line in the first semiconductor structure and a second connection line in the second semiconductor structure, and
wherein the second connection line comprises a first part overlapping with at least one of the row decoders or the string drivers, a second part overlapping with the first group of page buffers, and a third part connecting ends of the first part and the second part.

12. The memory device of claim 1, wherein the first semiconductor structure comprises a first bonding layer comprising first conductive structures isolated by a first isolating material,
wherein the second semiconductor structure comprises a second bonding layer comprising second conductive structures isolated by a second isolating material, and
wherein the first semiconductor structure and the second semiconductor structure are bonded together with the first conductive structures being in contact with the second conductive structures.

13. A method of forming a memory device, comprising:
forming a first semiconductor structure, wherein the first semiconductor structure comprises a first memory array in a first array region, a second memory array in a second array region, contact structures in a connection region between the first array region and the second array region along a first direction, and word lines coupled to memory cells in the first memory array and memory cells in the second memory array;
forming a second semiconductor structure comprising row decoders; and
stacking the first semiconductor structure and the second semiconductor structure along a second direction perpendicular to the first direction,
wherein at least one part of the row decoders overlaps with at least one of the first memory array in the first array region or the second memory array in the second array region in a plan view perpendicular to the second direction.

14. The method of claim 13, wherein the second semiconductor structure further comprises string drivers, wherein a string driver of the string drivers is coupled to a corresponding word line through a contact structure in the connection region and coupled to a corresponding row decoder, and wherein at least a first part of the string drivers overlaps with the at least one of the first memory array in the first array region or the second memory array in the second array region in the plan view.

15. The method of claim 14, wherein a second part of the string drivers overlaps with the connection region in the plan view.

16. The method of claim 14, wherein the row decoders comprise:
a first group of row decoders positioned on a first side of the string drivers; and
a second group of row decoders positioned on a second side of the string drivers.

17. The method of claim 16, wherein the first semiconductor structure comprises N memory blocks numbered from 0 to N-1,
wherein the first group of row decoders comprise a first row decoder coupled to first string drivers that are coupled to word lines in a first memory block associated with an odd number, and
wherein the second group of row decoders comprise a second row decoder coupled to second string drivers that are coupled to word lines in a second memory block associated with an even number.

18. The method of claim 17, wherein the first string drivers and the second string drivers are between the first row decoder and the second row decoder along the first direction, and wherein the odd number and the even number are adjacent integers.

19. The method of claim 14, wherein the second semiconductor structure further comprises a first group of page buffers and a second group of page buffers,
wherein the row decoders and the string drivers are positioned between the first group of page buffers and the second group of page buffers along the first direction,
wherein the first semiconductor structure further comprises bit lines coupled to the memory cells in the first memory array, wherein the bit lines are coupled to corresponding page buffers of the first group of page buffers, and wherein at least one part of at least one of the bit lines is distanced from a corresponding page buffer along the first direction in the plan view.

20. A memory system, comprising:
a memory device comprising:
a first semiconductor structure comprising a first memory array in a first array region, a second memory array in a second array region, contact structures in a connection region between the first array region and the second array region along a first direction, and word lines coupled to memory cells in the first memory array and memory cells in the second memory array; and
a second semiconductor structure comprising row decoders,
wherein the first semiconductor structure and the second semiconductor structure are stacked together along a second direction perpendicular to the first direction, and
wherein at least one part of the row decoders overlaps with at least one of the first memory array in the first array region or the second memory array in the second array region in a plan view perpendicular to the second direction; and
a controller coupled to the memory device and configured to control the memory device.
